(19) United States
(12) Patent Application Publication
(10) Pub. No.: US 2009/0250682 A1
(43) Pub. Date: Oct. 8, 2009

(54) PHASE CHANGE MEMORY DEVICE

(75) Inventors: Doo-Hwan Park, Seoul (KR); Yong-Ho Ha, Gyeonggi-do (KR); Myung-Jin Kang, Gyeonggi-do (KR); Jeong-Hee Park, Gyeonggi-do (KR); Hyun-Suk Kwon, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/406,344

(22) Filed: Mar. 18, 2009

(30) Foreign Application Priority Data
Apr. 8, 2008 (KR) 10-2008-0032765

(51) Int. Cl. H01L 45/00

(52) U.S. Cl. 257/4; 257/E45.002

(57) ABSTRACT

Provided is a phase change memory device. The phase change memory device includes a first electrode and a second electrode. A phase change material pattern is interposed between the first and second electrodes. A phase change auxiliary pattern is in contact with at least one side of the phase change material pattern. The phase change auxiliary pattern includes a compound having a chemical formula expressed as DₐM_{b}[GₓT_{y}]_{c}(0≦a/(a+b+c)≦0.2, 0≦b/(a+b+c)≦0.1, 0.3≦x/(x+y)≦0.7), where D comprises: at least one of C, N, and O; M comprises at least one of a transition metal, Al, Ga, and In; G comprises Ge; and T comprises Te.

### CROSS-REFERENCE TO RELATED APPLICATIONS

This U.S. non-provisional patent application claims priority under 35 U.S.C. §119 of Korean Patent Application No. 10-2008-0032765, filed on Apr. 8, 2008, the disclosure of which is hereby incorporated herein by reference in its entirety.

### FIELD OF THE INVENTION

The present invention disclosed herein relates to a semiconductor device, and more particularly, to a phase change memory device.

### BACKGROUND

Since a phase change material may represent at least two distinguishable states, i.e., an amorphous state and a crystalline state, and at least one of intermediate states, the phase change material may be used as a memory element. The amorphous state represents a relatively higher resistivity than the crystalline state, and the intermediate states represent a resistivity between the amorphous state and the crystalline state.

The state conversion of the phase change material may occur according to the temperature change, which may be induced, for example, by a resistance heating using an electric conductor connected to the phase change material. The resistance heating may be achieved by applying electrical signals such as a current to both ends of the phase change material.

### SUMMARY

The present invention provides a memory device having improved electrical characteristics and reliability, and a method of forming the same.

Embodiments of the invention provide phase change memory devices including: a first electrode and a second electrode; a phase change material pattern interposed between the first and second electrodes; and a phase change auxiliary pattern in contact with at least one side of the phase change material pattern, the phase change auxiliary pattern including a compound having a chemical formula expressed as DₐM_{b}[GₓT_{y}]_{c}(0≦a/(a+b+c)≦0.2, 0≦b/(a+b+c)≦0.1, 0.3≦x/(x+y)≦0.7), where D includes at least one of C, N, and O, M includes at least one of a transition metal, Al, Ga, and In, G includes Ge, and T includes Te.

In some embodiments, Gₓ may be Geₓ₁G′ₓ₂ (0.8≦x1/(x1+x2)≦1), G′ may be an element from groups 3A, 4A and 5A, G′ may be Al, Ga, In, Si, Sn, As, Sb, or Bi, and T_{y} maybe Te_{y1}Se_{y2} (0.8≦y1/(y1+y2)≦1).

In other embodiments, the phase change auxiliary pattern may be disposed between the phase change material pattern and the first electrode, or between the phase change material pattern and the second electrode.

In still other embodiments, the phase change memory device may further include an adhesive layer between the phase change auxiliary pattern and the first electrode or between the phase change auxiliary pattern and the second electrode. The adhesive layer may include at least one of a transition metal Al, Ga, and In.

In even other embodiments, the phase change memory device may further include a barrier layer between the phase change material pattern and the phase change auxiliary pattern. The barrier layer may include at least one of Ti, Ta, Mo, Hf, Zr, Cr, W, Nb, V, N, C, Al, B, P, O, and S. The barrier layer may include at least one of TiN, TiW, TiCN, TiAlN, TiSiC, TaN, TaSiN, MoN, and CN.

In yet other embodiments, the phase change material pattern may include a chalcogen compound. The chalcogen compound may include at least one of D1-Ge—Sb—Te, D2-Ge—Bi—Te, D3-Sb—Te, D4-Sb—Se, and D5-Sb. D1 may include at least one of C, N, Si, Bi, In, As, and Se. D2 may include at least one of C, N, Si, In, As, and Se. D3 may include at least one of As, Sn, SnIn, an element from group 5B, and an element from group 6B. D4 may include at least one of an element from group 5A and an element from group 6A. D5 may include at least one of Ge, Ga and In.

In further embodiments, the phase change material pattern may serve as a data storage element. The phase change auxiliary pattern may include a function of lowering the operation power of the phase change material pattern. The phase change auxiliary pattern may include a function of enhancing the retention characteristic and endurance characteristic of the phase change material pattern. [IS THERE ANY WAY TO QUANTIFY THIS?]

In other embodiments of the invention, phase change memory devices include: a lower electrode on a substrate; a phase change material pattern on the lower electrode; a phase change auxiliary pattern on the phase change material pattern; and an upper electrode on the phase change auxiliary pattern, the phase change auxiliary pattern including a compound having a chemical formula expressed as DₐM_{b}[GₓT_{y}]_{c}(0≦a/(a+b+c)≦0.2, 0≦b/(a+b+c)≦0.1, 0.3≦x/(x+y)≦0.7), where D includes at least one of C, N, and O, M includes at least one of a transition metal, Al, Ga, and In, G includes Ge, and T includes Te.

In some embodiments, Gₓ may be Geₓ₁G′ₓ₂ (0.8≦x1/(x1+x2)≦1), and G′ may be Al, Ga, In, Si, Sn, As, Sb, or Bi. T_{y} may be Te_{y1}Se_{y2} (0.8≦y1/(y1+y2)≦1).

In other embodiments, the phase change memory device may further include an insulating layer surrounding the phase change material pattern. The phase change auxiliary pattern may be disposed on the phase change material pattern and the insulating layer. The width of the phase change auxiliary pattern may be greater than the width of the phase change material pattern.

In still other embodiments, the phase change material pattern may be plate-shaped, cylinder-shaped, cup-shaped or ring-shaped.

In even other embodiments, the phase change memory device may further include an adhesive layer between the phase change auxiliary pattern and the upper electrode. The adhesive layer may include at least one of a transition metal, Al, Ga, and In.

In yet other embodiments, the phase change memory device may further include a barrier layer between the phase change material pattern and the phase change auxiliary pattern. The barrier layer may include at least one of Ti, Ta, Mo, Hf, Zr, Cr, W, Nb, V, N, C, Al, B, P, O, and S.

### BRIEF DESCRIPTION OF THE FIGURES

FIGS. 1 and 2A through 2C are diagrams illustrating a phase change memory device and a method of forming the same according to an embodiment of the invention. FIG. 1 is a plan view of the phase change memory device, and FIGS. 2A through 2C are cross-sectional views taken along the line I-I′ in FIG. 1;

FIGS. 3 and 4A through 4C are diagrams illustrating a phase change memory device and a method of forming the same according to another embodiment of the invention. FIG. 3 is a plan view of the phase change memory device, and FIGS. 4A through 4C are cross-sectional views taken along the line I-I′ in FIG. 3;

FIGS. 5 and 6A through 6D are diagrams illustrating a phase change memory device and a method of forming the same according to still another embodiment of the invention. FIG. 5 is a plan view of the phase change memory device, and FIGS. 6A through 6D are cross-sectional views taken along the line I-I′ in FIG. 5;

FIGS. 7 and 8A through 8D are diagrams illustrating a phase change memory device and a method of forming the same according to still another embodiment of the invention. FIG. 7 is a plan view of the phase change memory device, and FIGS. 8A through 8D are cross-sectional views taken along the line I-I′ in FIG. 7;

FIGS. 9 and 10A through 10F are diagrams illustrating a phase change memory device and a method of forming the same according to still another embodiment of the invention. FIG. 9 is a plan view of the phase change memory device, and FIGS. 10A through 10F are cross-sectional views taken along the line I-I′ in FIG. 9;

FIGS. 11 and 12A through 12F are diagrams illustrating a phase change memory device and a method of forming the same according to still another embodiment of the invention. FIG. 11 is a plan view of the phase change memory device, and FIGS. 12A through 12F are cross-sectional views taken along the line I-I′ in FIG. 11;

FIGS. 13A through 13C are diagrams illustrating the effect of a phase change memory device according to the embodiments of the invention; and

FIGS. 14 through 21 illustrate apparatuses including a phase change memory device according to embodiments of the invention.

### DETAILED DESCRIPTION OF EMBODIMENTS

Embodiments of the invention will be described below in more detail with reference to the accompanying drawings. The invention may, however, be embodied in different forms and should not be construed as limited to the embodiments set forth herein. Rather, these embodiments are provided so that this disclosure will be thorough and complete, and will fully convey the scope of the invention to those skilled in the art.

It will be understood that although the terms first and second are used herein to describe various elements, these elements should not be limited by these terms. These terms are only used to distinguish one element from another element. It will also be understood that when a layer (or film) is referred to as being ‘on’ another layer or substrate, it can be directly on the other layer or substrate, or intervening layers may also be present. In the figures, the dimensions of layers and regions are exaggerated for clarity of illustration. In the figures, the dimensions of layers and regions may be exaggerated for clarity of illustration. In addition, the sizes of elements and the relative sizes between the elements may be exaggerated for further understanding of the invention. Furthermore, shapes of the elements illustrated in the figures may vary with changes in the fabrication process. Therefore, it should be understood that the embodiments disclosed herein include some modifications without limitations to the shapes as illustrated in the figures.

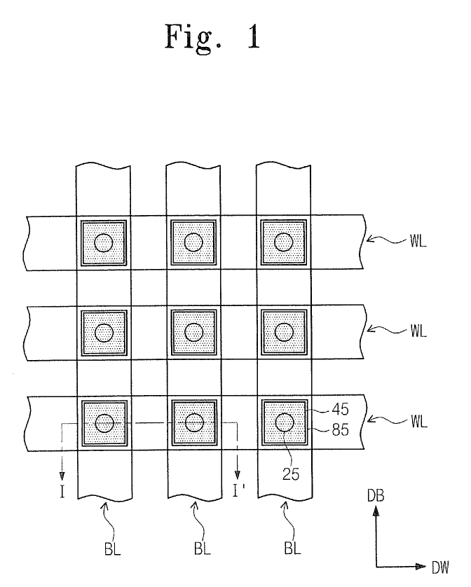

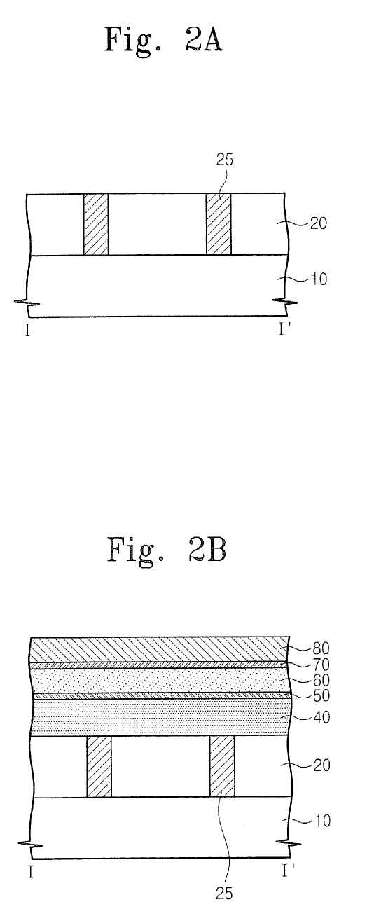

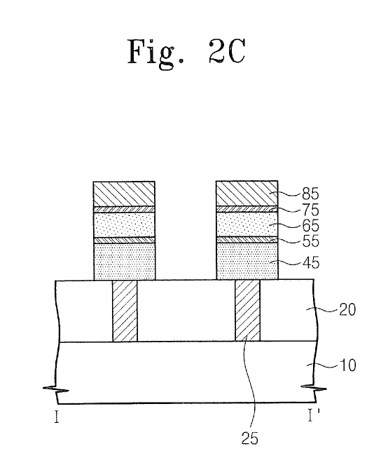

A phase change memory device and a method of forming the same according to an embodiment of the invention will be described in detail with reference to FIGS. 1 and 2A through 2C. FIG. 1 is a plan view of the phase change memory device, and FIGS. 2A through 2C are cross-sectional views taken along the line I-I′ in FIG. 1.

Referring to FIGS. 1 and 2A an interlayer dielectric 20 including a lower electrode 25 is formed on a substrate 10. The substrate 10 may be a semiconductor substrate including, e.g., a monocrystalline silicon substrate and a silicon on insulator (SOI) substrate. The substrate 10 may include a word line extending in a first direction DW. The substrate 10 may include a diode or a transistor electrically connected to the lower electrode 25. The diode may be positioned between the lower electrode 25 and the word line WL. For example, the interlayer dielectric 20 may be a silicon oxide, a silicon nitride, a silicon oxynitride, or a combination thereof. The interlayer dielectric 20 may be formed, for example, through a chemical vapor deposition (CVD) process. The lower electrode 25 may be formed, for example, by forming a conductive layer filling a contact hole in the interlayer dielectric 20 through CVD, atomic layer deposition (ALD) or physical vapor deposition (PVD) process and performing a planarization process such as a chemical physical polishing process or an etch back process. The lower electrode 25 may include, e.g., Ti, TiN, or a combination thereof.

Referring to FIGS. 1 and 2B, a phase change material layer 40, a barrier layer 50, a phase change auxiliary layer 60, an adhesive layer 70 and an upper electrode layer 80 may be formed on the interlayer dielectric 20 including the lower electrode 25. The phase change material layer 40, barrier layer 50, phase change auxiliary layer 60, adhesive layer 70 and upper electrode layer 80 may be formed, for example, through CVD, ALD, PVD or a sputtering process. The phase change material layer 40 may be formed to have a thickness of from about 100 Å to about 1,000 Å, and the barrier layer 50 may be formed to have a thickness of from about 10 Å to about 300 Å. The phase change auxiliary layer 60 may be formed to have a thickness of from about 100 Å to about 1,000 Å, and the adhesive layer 70 may be formed to have a thickness of from about 10 Å to about 100 Å. In an alternative embodiment, either or neither of the barrier layer 50 between the phase change material layer 40 and the phase change auxiliary layer 60, and the adhesive layer 70 between the phase change layer auxiliary layer 60 and the upper electrode layer 80 may be formed.

The phase change material layer 40 may include, e.g., a chalcogen compound. The chalcogen compound may include at least one of D1-Ge—Sb—Te, D2-Ge—Bi—Te, D3-Sb—Te, D4-Sb—Se, and D5-Sb. D1 may include at least one of C, N, Si, Bi, In, As, and Se. D2 may include at least one of C, N, Si, In, As, and Se. D3 may include at least one of As, Sn, SnIn, an element of group 5B, and an element of group 6B. D4 may include at least one of an element of group 5A and an element of group 6A. D5 may include at least one of Ge, Ga and In.

The barrier layer 50 may include at least one of Ti, Ta, Mo, Hf, Zr, Cr, W, Nb, V, N, C, Al, B, P, O, and S. For example, the barrier layer 50 may include at least one of TiN, TiW, TiCN, TiAlN, TiSiC, TaN, TaSiN, MoN, and CN. The barrier layer 50 may prevent the material diffusion between the phase change material layer 40 and the phase change auxiliary layer 60.

The phase change auxiliary layer 60 may include a compound having a chemical formula expressed as DₐM_{b}[GₓT_{y}]_{c}(0≦a/(a+b+c)≦0.2, 0≦b/(a+b+c)≦0.1, 0.3≦x/(x+y)≦0.7). In the chemical formula, D may include at least one of C, N and O. M may include at least one of a transition metal, Al, Ga, and In. G may include Ge, T may include Te. In the chemical formula, Gₓ may be Geₓ₁G′ₓ₂ (0.8≦x1/(x1+x2)≦1). G′ may be an element from groups 3A, 4A and 5A. For example, G′ may be Al, Ga, In, Si, Sn, As, Sb, or Bi. T_{y} may be Te_{y1}Se_{y2} (0.8≦y1/(y1+y2)≦1).

The adhesive layer 70 may include, e.g., at least one of transition metal, Al, Ga, and In. The adhesive layer 70 may allow the upper electrode layer 80 to be deposited on the phase change auxiliary layer 60. The upper electrode layer 80 may include a conductive material, e.g., Ti, TiN, or a combination thereof.

Referring to FIGS. 1 and 2C, the upper electrode layer 80, adhesive layer 70, phase change auxiliary layer 60, barrier layer 50 and phase change material layer 40 are patterned to form an upper electrode 85, an adhesive pattern 75, a phase change auxiliary pattern 65, a barrier pattern 55, and a phase change material pattern 45, respectively. The phase change auxiliary layer 60 may be in contact with at least one side of the phase change material layer 40. A bit line BL extending in a second direction DB may be formed on the upper electrode 85. The bit line BL may be connected to the upper electrodes 85 arranged in the second direction DB. Although the upper electrode 85, adhesive pattern 75, phase change auxiliary pattern 65, barrier pattern 55 and phase change material pattern 45 are arranged in an island form along the first and second directions, DW and DB in this embodiment, they may be arranged in a different form in other embodiments, the selection of which will be within the skill of one in the art. For example, the upper electrode 85, adhesive pattern 75, phase change auxiliary pattern 65, barrier pattern 55 and phase change material pattern 45 may be formed in a linear form extending in the second direction DB. Also, the upper electrode 85 may serve as a bit line BL.

The phase change material pattern 45 may serve as a data storage element storing data according to the resistance of crystalline or amorphous state. The lower electrode 25 and upper electrode 85 may provide a signal to change the state of the phase change material pattern 45. Depending on heat generated by the signal, the phase change material pattern 45 may be reversibly converted into a crystalline state or an amorphous state having different resistances from each other. The signal, which is to change the phase change material pattern 45 into the crystalline or amorphous state, may include an electrical signal such as current and voltage, an optical signal, or a radiation. For example, if a current flows between the lower electrode 25 and the upper electrode 85, the phase change material pattern 45 is heated by resistance heating to be melted. Then, the phase change material pattern 45 is cooled into the crystalline or amorphous state. The state of the phase change material pattern may be dependent on heating temperature, heating time, and cooling speed.

The phase change auxiliary pattern 65 may reduce the operation power of the phase change material pattern 45. Also, the phase change auxiliary pattern 65 may enhance the retention and endurance characteristics of the phase change material pattern 45.

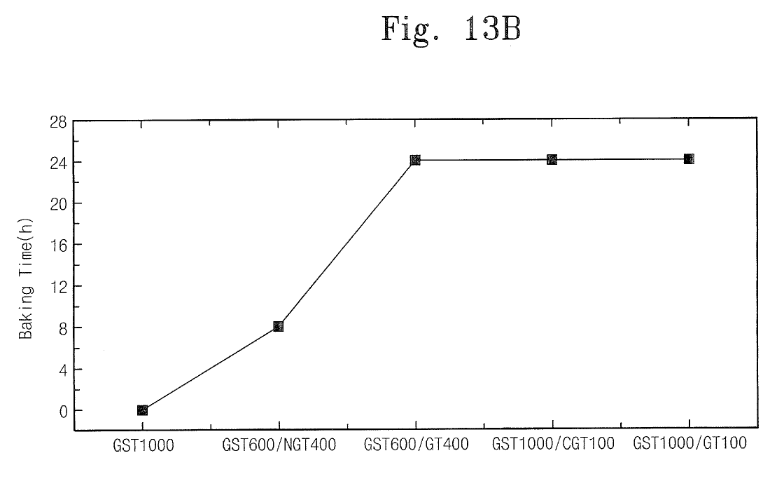

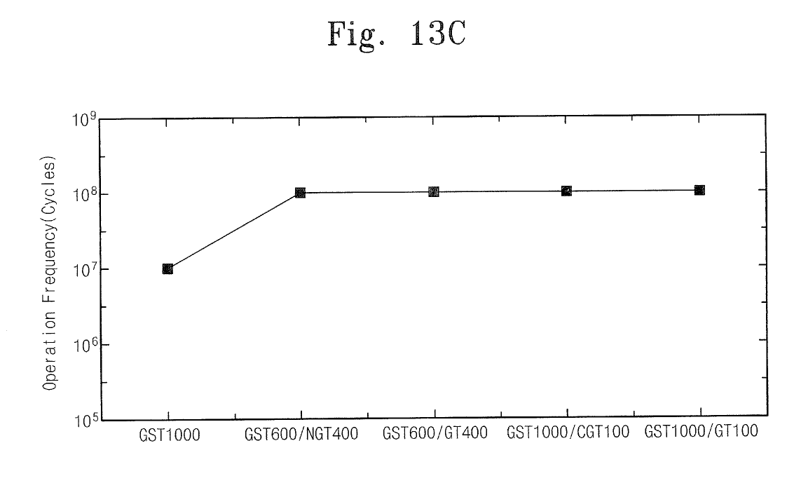

FIGS. 13A through 13C show the effect of the phase change memory device according to embodiments of the invention including the phase change auxiliary pattern 65. Horizontal axes in graphs in FIGS. 13A through 13C show compositions of the phase change material pattern and phase change auxiliary pattern. That is, GST1000 represents a phase change memory device including no phase change auxiliary pattern and a phase change material pattern of about 1000 Å. GST600/NGT400 represents a phase change memory device including a phase change material pattern of about 600 Å formed of Ge—Sb—Te and a phase change auxiliary pattern of about 400 Å formed of N−Ge—Te, and GST600/GT400 represents a phase change memory device including a phase change material pattern of about 600 Å formed of Ge—Sb—Te and a phase change auxiliary pattern of about 400 Å formed of Ge—Te. GST1000/CGT100 represents a phase change memory device including a phase change material pattern of about 1000 Å formed of Ge—Sb—Te and a phase change auxiliary pattern of about 100 Å formed of C—Ge—Te, and GST1000/GT100 represents a phase change memory device including a phase change material pattern of about 1000 Å formed of Ge—Sb—Te and a phase change auxiliary pattern of about 100 Å formed of Ge—Te. The vertical axes represent reset current, baking time, and operation frequency, respectively.

Referring to FIG. 13A, a reset current in a phase change memory device including a phase change auxiliary pattern was smaller than that in a phase change memory device excluding the phase change auxiliary pattern. Referring to FIG. 13B, a phase change memory device including a phase change auxiliary pattern operates normally even when heated for about 24 hours at a temperature of about 150° C. Referring to FIG. 13C, an operation frequency in a phase change memory device including a phase change auxiliary pattern is about 10 times greater than that in a phase change memory device excluding a phase change auxiliary pattern. As described in FIGS. 13A through 13C, it will be understood that a phase change memory device including a phase change auxiliary pattern according to embodiments of the invention has an excellent operation power, retention characteristic, and endurance characteristic.

Hereinafter, a phase change memory device according to another embodiment of the invention will be described. The above descriptions of the substrate, lower electrode, phase change material pattern, barrier layer, phase change auxiliary pattern, adhesive layer and upper electrode that are elements of the phase change memory device, composition material, formation process, thickness, structure and shape of the interlayer dielectric, and relations therebetween will be identically applied to this embodiment unless specifically referred to.

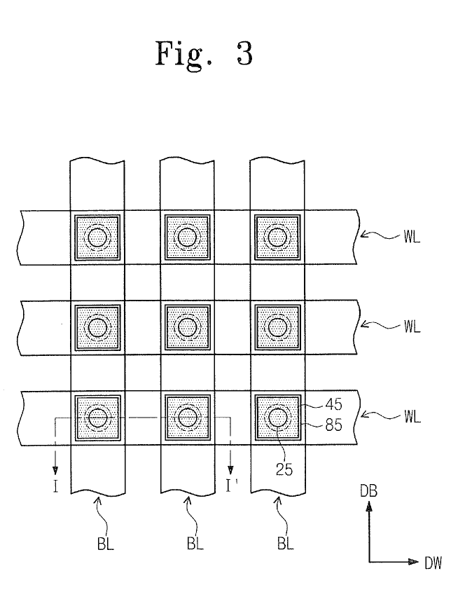

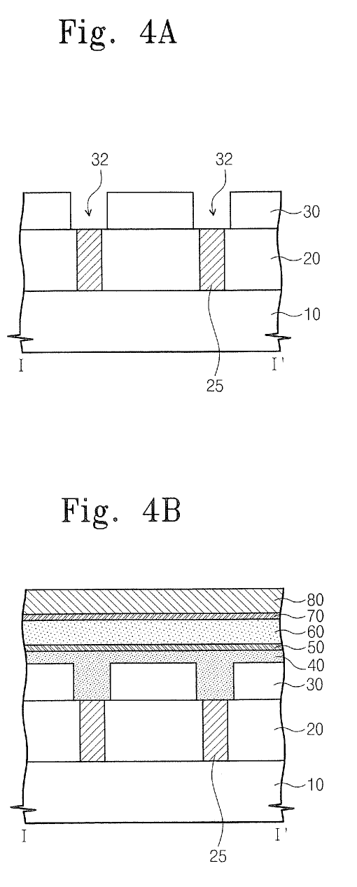

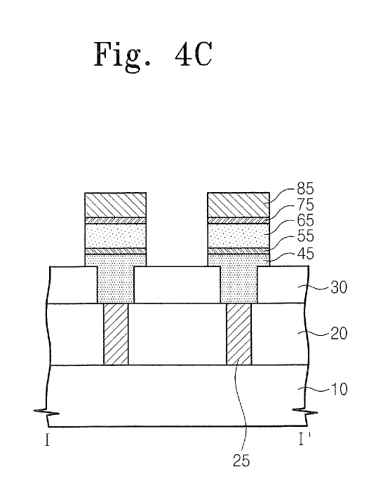

A phase change memory device and a method for manufacturing the same will be described in detail with reference to FIGS. 3 and 4A through 4C. FIG. 3 is a plan view of the phase change memory device, and FIGS. 4A through 4C are cross-sectional views taken along the line I-I′ in FIG. 3.

Referring to FIGS. 3 and 4A, a first interlayer dielectric 20 including a lower electrode 25 is formed on a substrate 10. A second interlayer dielectric 30 having an opening 32 exposing the lower electrode 25 is formed on the first interlayer dielectric 20.

Referring to FIGS. 3 and 4B, a phase change material layer 40 is formed on the second interlayer dielectric 30 to fill the opening 32 and is connected to the lower electrode 25. A barrier layer 50, a phase change auxiliary layer 60, an adhesive layer 70, and an upper electrode layer 80 are formed on the phase change material layer 40.

Referring to FIGS. 3 and 4C, the upper electrode layer 80, adhesive layer 70, phase change auxiliary layer 60, barrier layer 50, and phase change material layer 40 are patterned to form an upper electrode 85, an adhesive pattern 75, a phase change auxiliary pattern 65, a barrier pattern 55, and a phase change material pattern 45, respectively. The phase change material pattern 45 may have a lower part in the opening 32 and an upper part above the second interlayer dielectric 30. The width of the upper part may be greater than that of the lower part.

In an alternative embodiment, the upper electrode 85, adhesive pattern 75, phase change auxiliary pattern 65, barrier pattern 55, and phase change material pattern 45 may be formed extending in a second direction DB. The upper electrode 85 extending in the second direction DB may serve as a bit line BL.

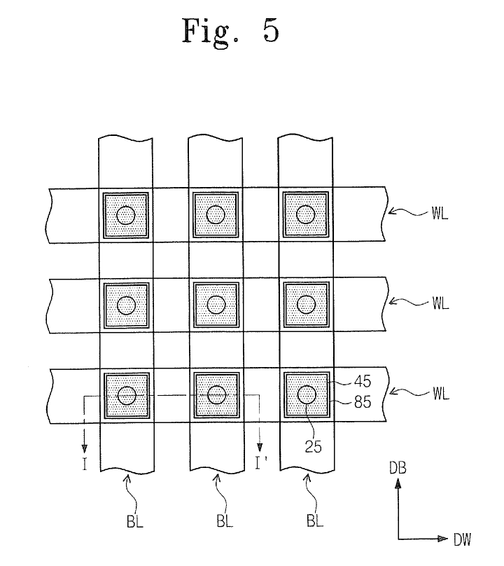

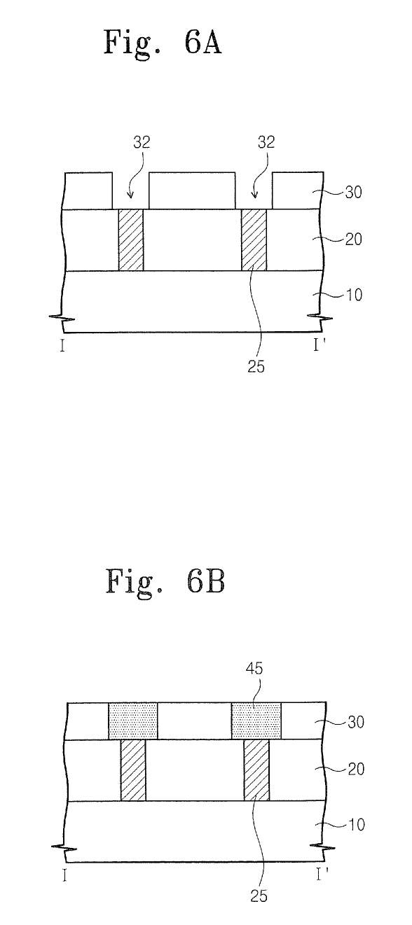

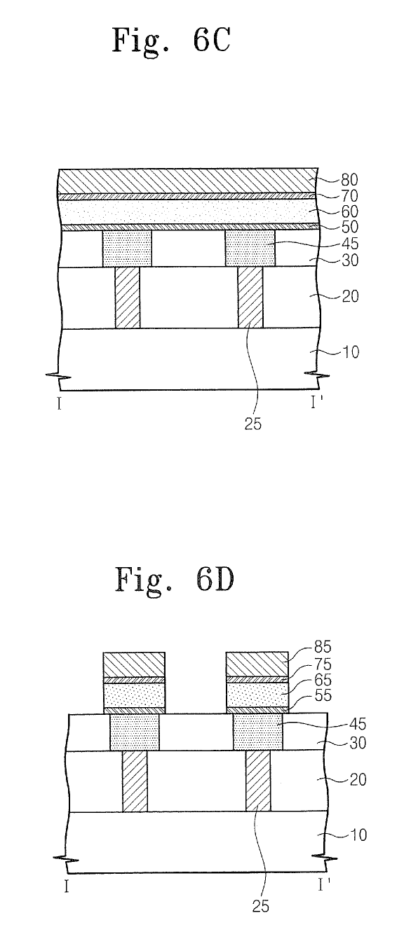

A phase change memory device and a method for manufacturing the same according to still another embodiment of the invention will be described in detail with reference to FIGS. 5 and 6A through 6D. FIG. 5 is a plan view of the phase change memory device, and FIGS. 6A through 6D are cross-sectional views taken along the line I-I′ in FIG. 5.

Referring to FIGS. 5 and 6A, a first interlayer dielectric 20 including a lower electrode 25 is formed on a substrate 10. A second interlayer dielectric 30 having an opening 32 exposing the lower electrode 25 is formed on the first interlayer dielectric 20.

Referring to FIGS. 5 and 6B, a phase change material pattern 45 is formed in the opening 32. The phase change material pattern 45 may be formed through a planarization process exposing the upper surface of the second interlayer dielectric 30 after a phase change material layer is formed in the opening 32. The planarization process may be, e.g., a CMP process or an etch back process.

Referring to FIGS. 5 and 6C, a barrier layer 50, a phase change auxiliary layer 60, an adhesive layer 70, and an upper electrode layer 80 are formed on the phase change material pattern 45 and the second interlayer dielectric 30.

Referring to FIGS. 5 and 6D, the upper electrode layer 80, adhesive layer 70, phase change auxiliary layer 60, and barrier layer 50 are patterned to form an upper electrode 85, an adhesive pattern 75, a phase change auxiliary pattern 65, and a barrier pattern 55. The widths of the upper electrode 85, adhesive pattern 75, phase change auxiliary pattern 65, and barrier pattern 55 may be greater than that of the phase change material pattern 45.

In an alternative embodiment, the upper electrode 85, adhesive pattern 75, phase change auxiliary pattern 65, and barrier pattern 55 may be formed to extend in a second direction DB. The upper electrode 85 extending in the second direction DB may serve as a bit line BL.

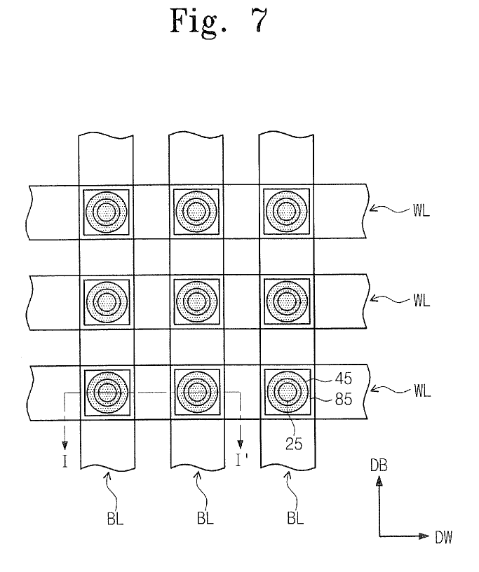

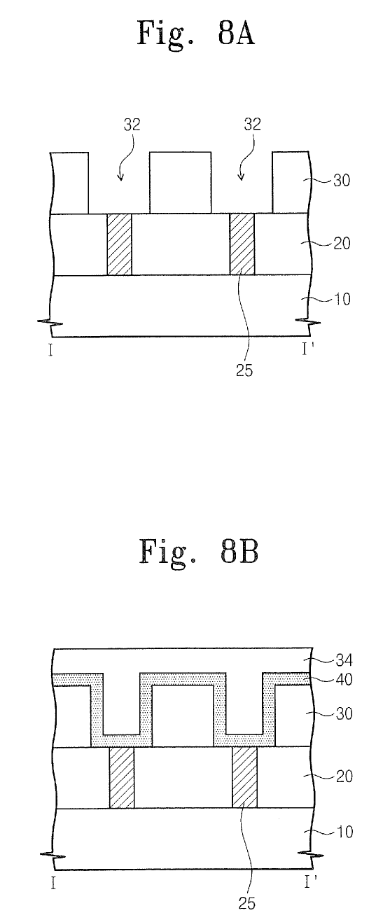

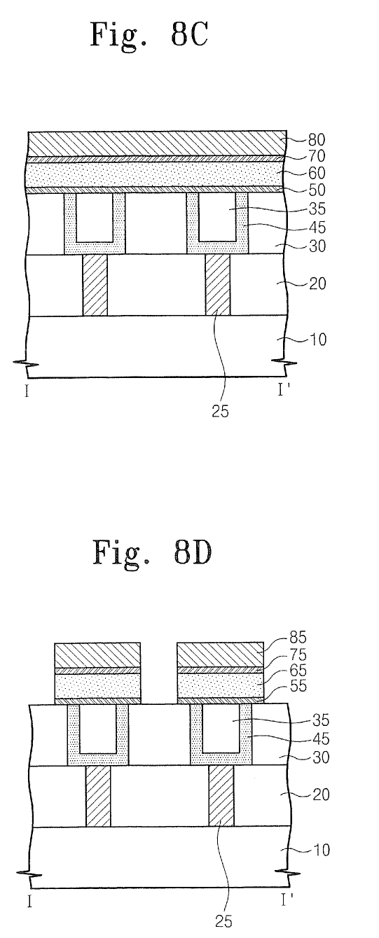

A phase change memory device and a method for manufacturing the same according to still another embodiment of the invention will be described in detail with reference to FIGS. 7 and 8A through 8D. FIG. 7 is a plan view of the phase change memory device, and FIGS. 8A through 8D are cross-sectional views taken along the line I-I′ in FIG. 7.

Referring to FIGS. 7 and 8A, a first interlayer dielectric 20 including a lower electrode 25 is formed on a substrate 10. A second interlayer dielectric 30 having an opening 32 is formed on the first interlayer dielectric 20. The opening 32 may expose the lower electrode 25.

Referring to FIGS. 7 and 8B, a phase change material layer 40 is formed along the side surface and bottom surface of the opening 32, and the top surface of the second interlayer dielectric 30. The phase change material layer 40 may be formed to have a uniform thickness. A filling insulating layer 34 is formed on the phase change material layer 40 to fill the opening 32. For example, the filling insulating layer 34 may be formed of a metal oxide, a silicon oxide, a silicon oxynitride, or a combination thereof. For example, the filling insulating layer 34 may include a titanium oxide, a tantalum oxide, a zirconium oxide, a manganese oxide, a hafnium oxide, a magnesium oxide, an indium oxide, a niobium oxide, a germanium oxide, an antimony oxide, a tellurium oxide, or a combination thereof. The filling insulating layer 34 may be formed, for example, through a CVD process.

Referring to FIGS. 7 and 8C, a planarization process exposing the top surface of the second interlayer dielectric 30 is performed to form a phase change material pattern 45 and a filling pattern 35 in the opening 32. The filling pattern 35 may have a cylindrical shape. The phase change material pattern 45 may be a cup-shaped cylinder surrounding the side surface and lower surface of the filling pattern 35.

A barrier layer 50, a phase change auxiliary layer 60, an adhesive layer 70 and an upper electrode layer 80 are formed on the second interlayer dielectric 30, filling pattern 35 and phase change material pattern 45.

Referring to FIGS. 7 and 8D, the upper electrode layer 80, adhesive layer 70, phase change auxiliary layer 60, and barrier layer 50 are patterned to form an upper electrode 85, an adhesive pattern 75, a phase change auxiliary pattern 65, and a barrier pattern 55, respectively. The upper electrode 85, adhesive pattern 75, phase change auxiliary pattern 65, and barrier pattern 55 may cover the top surfaces of the phase change material pattern 45 and filling pattern 35.

In an alternative embodiment, the upper electrode 85, adhesive pattern 75, phase change auxiliary pattern 65, and barrier pattern 55 may be formed to extend in a second direction DB. The upper electrode 85 extending in the second direction DB may serve as a bit line BL.

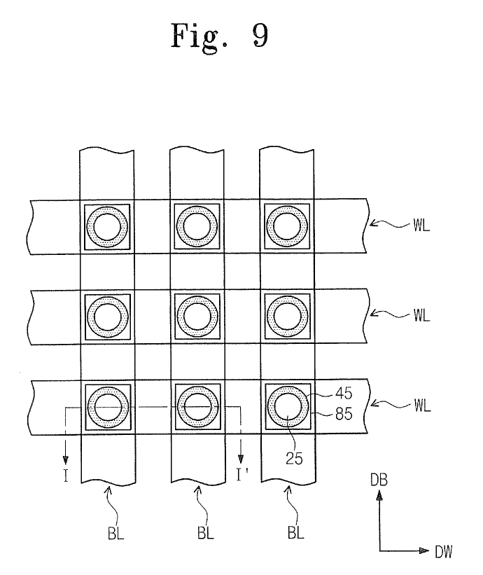

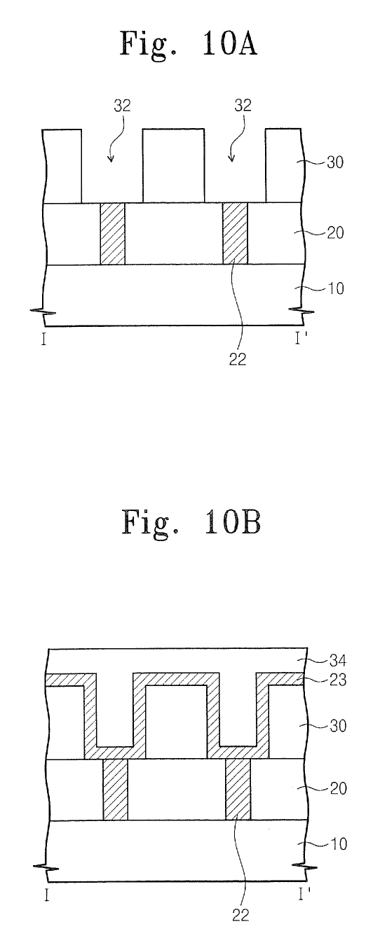

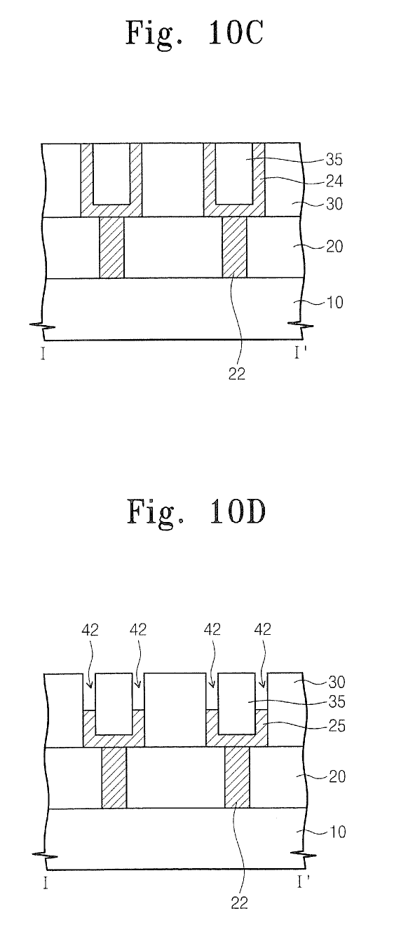

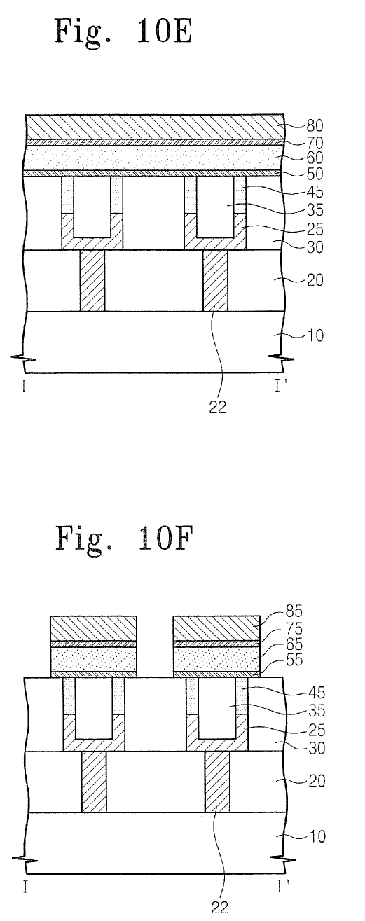

A phase change memory device and a method for manufacturing the same according to still another embodiment of the invention will be described in detail with reference to FIGS. 9 and 10A through 10F. FIG. 9 is a plan view of the phase change memory device, and FIGS. 10A through 10F are cross-sectional views taken along the line I-I′ in FIG. 9.

Referring to FIGS. 9 and 10A, a first interlayer dielectric 20 including a lower electrode contact 25 is formed on a substrate 10. A second interlayer dielectric 30 having an opening 32 exposing the lower electrode contact 25 is formed on the first interlayer dielectric 20. The lower electrode contact 25 may be formed of a conductive material, e.g., tungsten.

Referring to FIGS. 9 and 10B, a lower electrode layer 23 is formed along the side surface and bottom surface of the opening 32, and the top surface of the second interlayer dielectric 30. The lower electrode layer 23 may be formed to have a uniform thickness. A filling insulating layer 34 is formed on the lower electrode layer 23 to fill the opening 32. For example, the filling insulating layer 34 may include a metal oxide, a silicon oxide, a silicon oxynitride, or a combination thereof. In some embodiments, the filling insulating layer 34 may include a titanium oxide, a tantalum oxide, a zirconium oxide, a manganese oxide, a hafnium oxide, a magnesium oxide, an indium oxide, a niobium oxide, a germanium oxide, an antimony oxide, a tellurium oxide, or a combination thereof. The filling insulating layer 34 may be formed, for example, through a CVD process.

Referring to FIGS. 9 and 10C, a planarization process exposing the top surface of the second interlayer dielectric 30 is performed to form a lower electrode pattern 24 and a filling pattern 35. The filling pattern 35 may have a cylindrical shape. The lower electrode pattern 24 may be a cup-shaped surrounding the side surface and lower surface of the filling pattern 35.

Referring to FIGS. 9 and 10D, the upper part of the lower electrode pattern 24 is recessed through an etching process to form a lower electrode 25. A recess region 42 is formed between the second interlayer 30 and the filling pattern 35. In the etching process, the lower electrode pattern 24 may be selectively etched with respect to the second interlayer dielectric 30 and the filling pattern 35.

Referring to FIGS. 9 and 10E, a phase change material pattern 45 is formed in the recess region 42. The phase change material pattern 45 may be formed through a planarization process exposing the top surfaces of the second interlayer dielectric 30 and filling pattern 35 after a phase change material layer fills the recess region 42. The planarization process may be, for example, a CMP process or an etch back process.

Barrier layer 50, phase change auxiliary layer 60, adhesive layer 70, and upper electrode layer 80 are formed on the second interlayer dielectric 30, phase change material pattern 45, and filling pattern 35.

Referring to FIGS. 9 and 10F, the upper electrode layer 80, adhesive layer 70, phase change auxiliary layer 60, and barrier layer 50 are patterned to form an upper electrode 85, an adhesive pattern 75, a phase change auxiliary pattern 65, and a barrier pattern 55, respectively. The upper electrode 85, adhesive pattern 75, phase change auxiliary pattern 65, and barrier pattern 55 may cover the top surfaces of the phase change material pattern 45 and filling pattern 35.

In an alternative embodiment, the upper electrode 85, adhesive pattern 75, phase change auxiliary pattern 65, and barrier pattern 55 may be formed to extend in a second direction DB. The upper electrode 85 extending in the second direction DB may serve as a bit line BL.

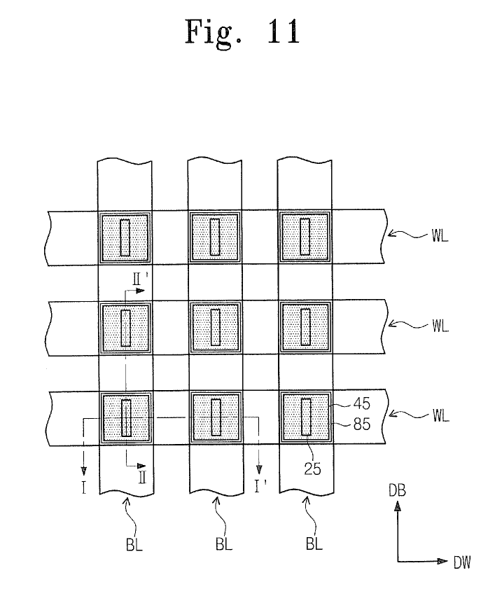

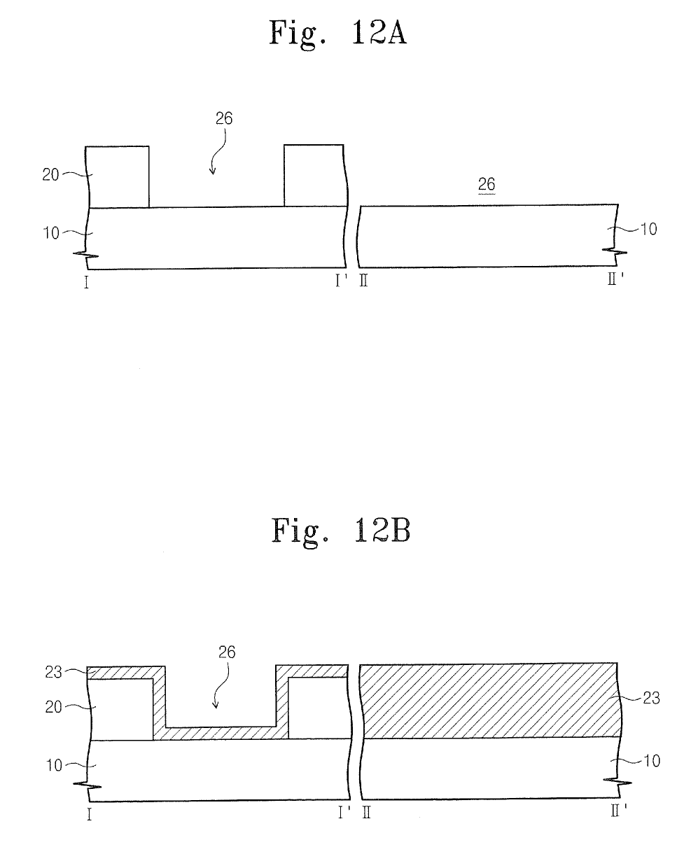

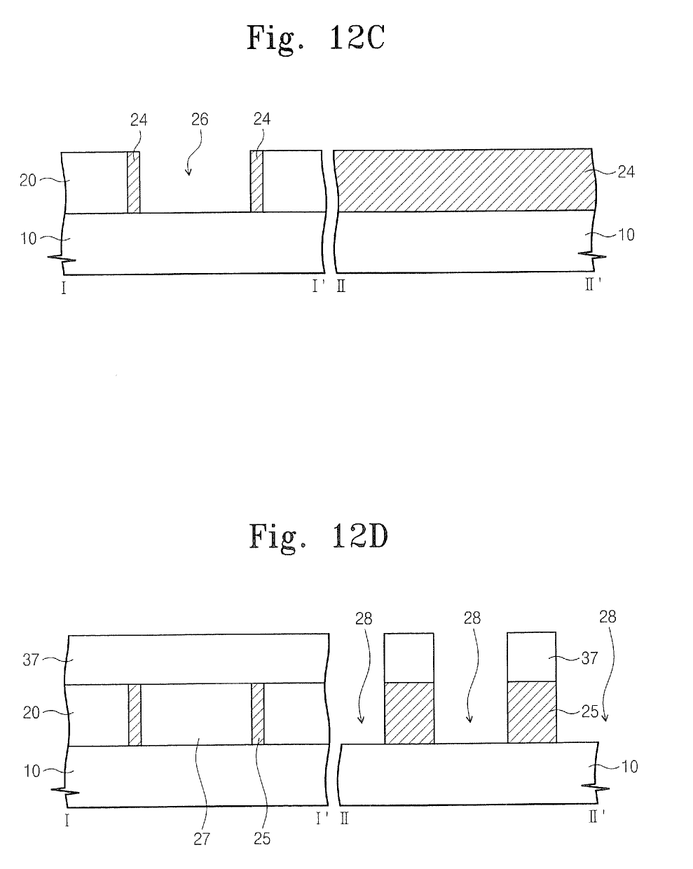

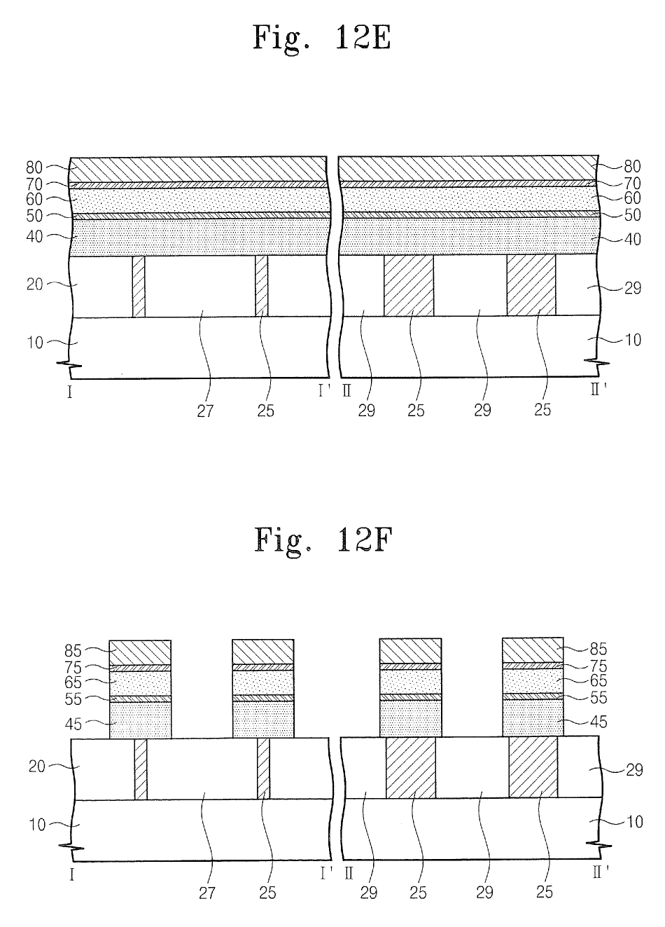

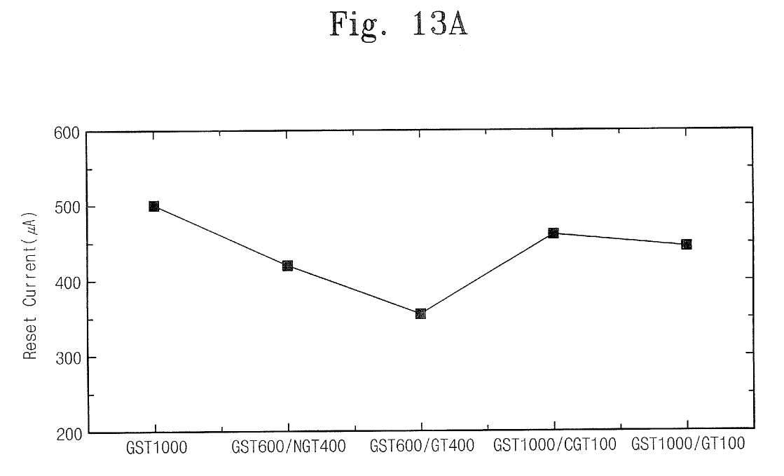

A phase change memory device and a method for manufacturing the same will be described in detail with reference to FIGS. 11 and 12A through 12F. FIG. 11 is a plan view of the phase change memory device, and FIGS. 12A through 12F are cross-sectional views taken along the lines I-I′ and II-II′ in FIG. 11.

Referring to FIGS. 11 and 12A, a first interlayer dielectric 20 having an opening 26 is formed on a substrate 10. The opening 26 may be extended a second direction DB thereby exposing the substrate 10.

Referring to FIGS. 11 and 12B, a lower electrode layer 23 is formed along the both side surfaces and bottom surface of the opening 26, and the top surface of the interlayer dielectric 20. The lower electrode layer 23 is formed to have a uniform thickness. The side surfaces and bottom surface of the opening 26 may be side surfaces of the interlayer dielectric 20 and the top surface of the exposed substrate 10, respectively.

Referring to FIGS. 11 and 12C, a lower electrode pattern 24 is formed on both side surfaces of the opening 26. The lower electrode pattern 24 may be formed by a anisotropic etching of the lower electrode layer 23. The top surfaces of the interlayer dielectric 20 and substrate 10 are exposed by the anisotropic etching. The lower electrode pattern 24 may be extended toward the second direction DB.

Referring to FIGS. 11 and 12D, a first filling pattern 27 is formed in the opening 26. The first filling pattern 27 may be extended toward the second direction DB. The first filling pattern 27 may be formed, for example, through a planarization process exposing the top surfaces of the interlayer layer 20 and lower electrode pattern 24 after a filling insulating layer is formed on the interlayer dielectric 20 to fill the opening 26. The planarization process may be, e.g., a CMP process or an etch back process. The first filling pattern 27 may be formed of, e.g., a silicon oxide, a silicon nitride, or a silicon oxynitride. After filling the opening 26, the filling insulating layer is formed on the lower electrode layer 23. The planarization process may be performed to simultaneously form the lower electrode pattern 24 and the first filling pattern 27.

A mask pattern 37 extending to a first direction DW is formed on the first filling pattern, lower electrode pattern 24, and interlayer dielectric 20. An opening 28 extending in the first direction is formed by etching the lower electrode pattern 24, interlayer dielectric 20, and first filling pattern 27 using the mask pattern 37 as an etch mask. The lower electrode pattern 24 is patterned to form a lower electrode 25 under the mask pattern 37. The lower electrode 25 may be arranged in the first and second directions DW and DB.

Referring to FIGS. 11 and 12E, a second filling pattern 29 is formed in the opening 28. The second filling pattern 29 may be extended toward the first direction DW. The second pattern 29 may be formed through a planarization process exposing the top surfaces of the interlayer dielectric 20, lower electrode 25, and first filling pattern 27 after a filling insulating layer is formed to fill the opening 28. The planarization process may be, e.g., a CMP process or an etch back process. The second filling pattern 29 may be formed of, e.g., a silicon oxide, a silicon nitride, or a silicon oxynitride.

A barrier 50, a phase change auxiliary layer 60, an adhesive layer 70, and an upper electrode layer 80 may be formed on the first filling pattern 27, the second filling pattern 29, and the interlayer dielectric 20.

Referring to FIGS. 11 and 12F, the upper electrode layer 80, adhesive layer 70, phase change auxiliary layer 60, and barrier layer 50 are patterned to form an upper electrode 85, an adhesive pattern 75, a phase change auxiliary pattern 65, and a barrier pattern 55, respectively. The upper electrode 85, adhesive pattern 75, phase change auxiliary pattern 65, and barrier pattern 55 may cover the top surface of a phase change material pattern 45.

The upper electrode 85, adhesive pattern 75, phase change auxiliary pattern 65, and barrier pattern 55 may also be patterned to extend in the second direction DB. The upper electrode 85 extending in the second direction DB may serve as a bit line BL.

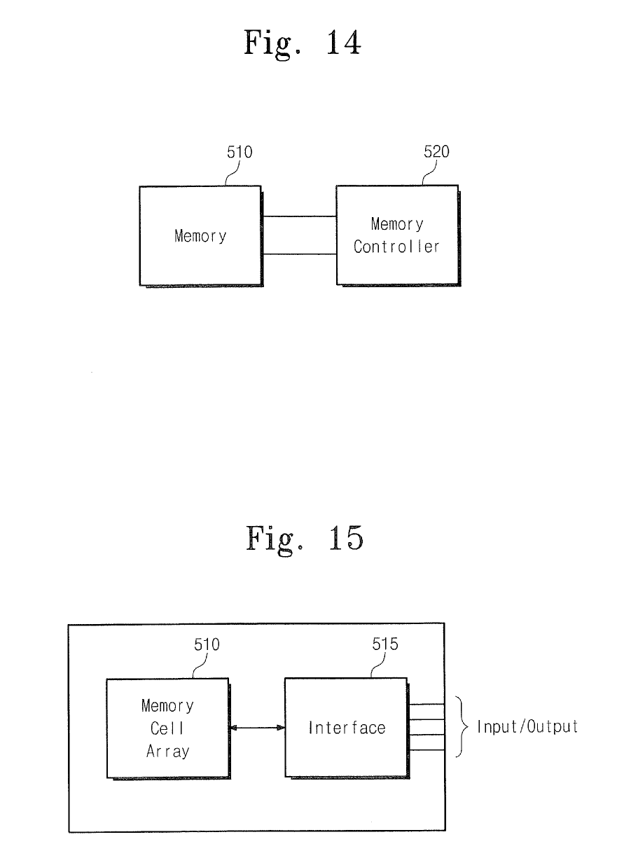

FIG. 14 illustrates an apparatus including a resistive memory device according to an embodiment of the invention. As shown in the drawing, the apparatus of this embodiment includes a memory 510 and a memory controller 520. The memory 510 may include a resistive memory device according to the above-described embodiments of the invention. The memory controller 520 may supply an input signal for controlling an operation of the memory 510. For example, the memory controller 520 may supply a command language and an address signal. The memory controller 520 may control the memory 510 based on a received control signal.

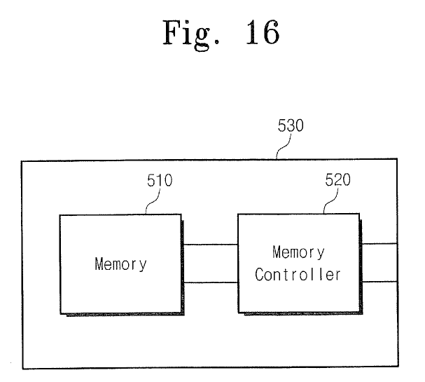

FIG. 15 illustrates an apparatus including a resistive memory device according to an embodiment of the invention. As shown in the drawing, the apparatus of this embodiment includes a memory 510 connected with an interface 515. The memory 510 may include a memory device according to the aforementioned embodiments of the invention. The interface 515 may provide, for example, an external input signal. For example, the interface 515 may provide a command language and an address signal. The interface 515 may control the memory 510 based on a control signal which may be generated from an outside source and received.

FIG. 16 illustrates an apparatus including a resistive memory device according to an embodiment of the invention. As shown in the drawing, the apparatus of the invention is similar to the apparatus of FIG. 10 except that the memory 510 and the memory controller 520 are embodied by a memory card 530. For example, the memory card 530 may be a memory card satisfying a standard for compatibility with electronic appliances, such as digital cameras, personal computers or the like. The memory controller 520 may control the memory 510 based on a control signal which the memory card receives from a different device, for example, an external device.

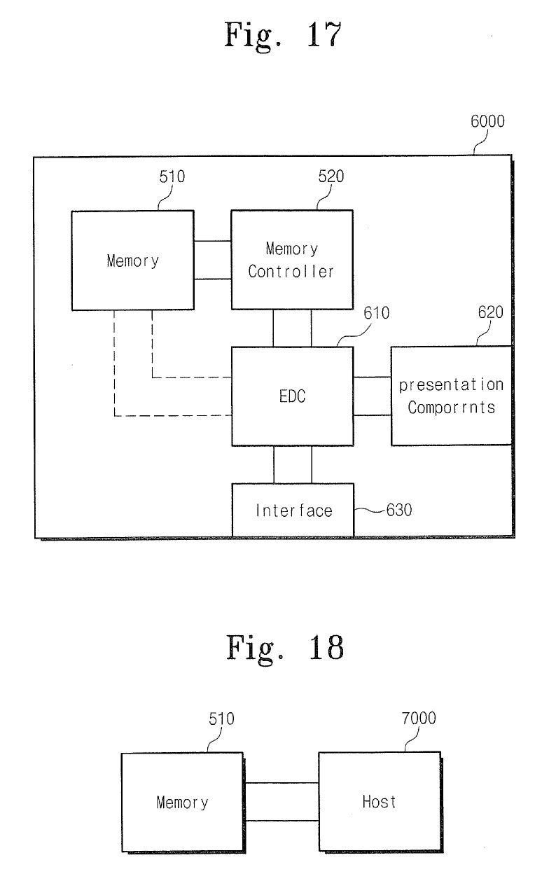

FIG. 17 illustrates a mobile device 6000 including a resistive memory device according to an embodiment of the invention. The mobile device 6000 may be an MP3, a video player, a video, audio player or the like. As shown in the drawing, the mobile device 6000 includes a memory 510 and a memory controller 520. The memory 510 includes a resistive memory device according to the aforementioned embodiments of the invention. The mobile device 6000 may include an encoder and decoder EDC 610, a presentation component 620, and an interface 630. Data such as videos and audios may be exchanged between the memory 510 and the encoder and decoder EDC 610 via the memory controller 520. As indicated by a dotted line, data may be directly exchanged between the memory 510 and the encoder and decoder EDC 610.

EDC 610 may encode data to be stored in the memory 510. For example, EDC 610 may encode an audio data into an MP3 file and store the encoded MP3 file in the memory 510. Alternatively, EDC 610 may encode MPEG video data (e.g., MPEG3, MPEG4, etc.) and store the encoded video data in the memory 510. Also, EDC 610 may include a plurality of encoders that encode a different type of data according to a different data format. For example, EDC 610 may include an MP3 encoder for audio data and an MPEG encoder for video data. EDC 610 may decode output data from the memory 510. For example, EDC 610 may decode audio data outputted from the memory 510 into an MP3 file. Alternatively, EDC 610 may decode video data outputted from the memory 510 into an MPEG file. Also, EDC 610 may include a plurality of decoders that decode a different type of data according to a different data format. For example, EDC 610 may include an MP3 decoder for audio data and an MPEG decoder for video data. Also, EDC 610 may include only a decoder. For example, previously encoded data may be delivered to EDC 610, decoded and then delivered to the memory controller 520 and/or the memory 510.

EDC 610 receives data for encoding or previously encoded data via the interface 630. The interface 630 may comply with a well-known standard (e.g., USB, firewire, etc.). The interface 630 may include one or more interfaces. For example, the interface 630 may include a firewire interface, a USB interface, etc. The data provided from the memory 510 may be outputted via the interface 630.

The representation component 620 represents data decoded by the memory 510 and/or EDC 610 such that a user can perceive the decoded data. For example, the representation component 620 may include a display screen displaying a video data, etc., and a speaker jack for outputting an audio data.

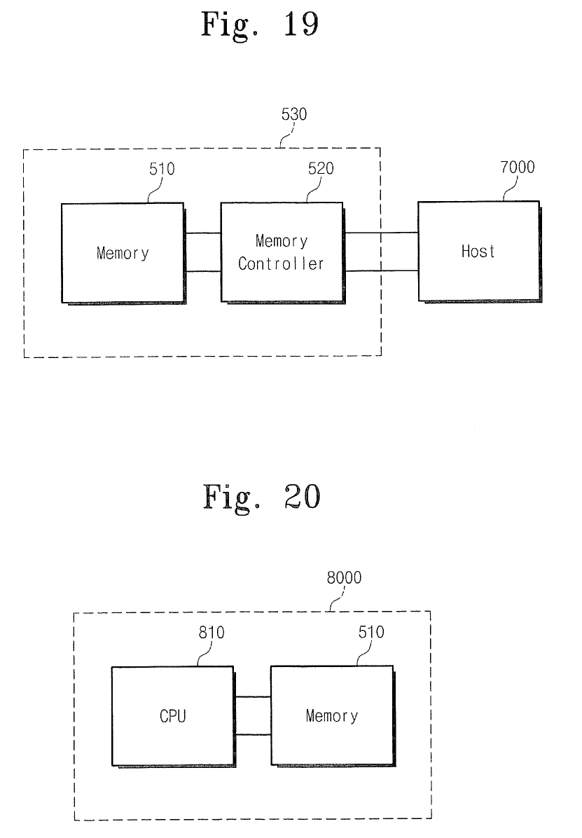

FIG. 18 illustrates an apparatus including a resistive memory device according to an embodiment of the invention. As shown in the drawing, the memory 510 may be connected with a host system 7000. The memory 510 may include a resistive memory device according to the aforementioned embodiments of the invention. The host system 7000 may be a processing system such as a personal computer, a digital camera, etc. The memory 510 may be a detachable storage medium form, for example, a memory card, a USB memory, or a solid-state driver SSD. The host system 7000 may provide an input signal for controlling an operation of the memory 510. For example, the host system 7000 may provide a command language and an address signal.

FIG. 19 illustrates an apparatus including a resistive memory device according to an embodiment of the invention. In this embodiment, a host system 7000 is connected with a memory card 530. The host system 7000 supplies a control signal to the memory card 530 such that a memory controller 520 controls an operation of a memory 510.

FIG. 20 illustrates an apparatus including a resistive memory device according to an embodiment of the invention. As shown in the drawing, according to the apparatus of this embodiment, a memory 510 may be connected with a central processing unit CPU 810 in a computer system 8000. For example, the computer system 8000 may be a personal computer, a personal data assistant, etc. The memory 510 may be connected with the CPU 810 via a bus.

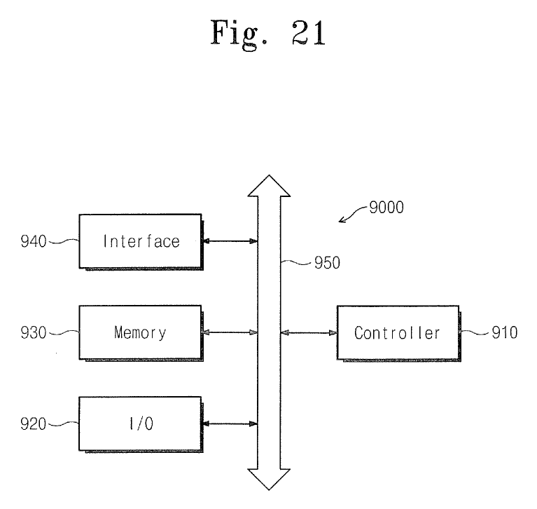

FIG. 21 illustrates an apparatus including a resistive memory device according to an embodiment of the invention. As shown in the drawing, the apparatus 9000 according to this embodiment may include a controller 910, an input/output unit 920 such as a keyboard, a display or the like, a memory 930, and an interface 940. In this embodiment, the respective components constituting the apparatus may be connected with each other via a bus 950.

The controller 910 may include at least one microprocessor, digital processor, microcontroller, or processor. The memory 930 may store a command executed by data and/or the controller 910. The interface 940 may be used to transmit data from a different system, for example, a communication network, or to a communication network. The apparatus 9000 may be a mobile system such as a PDA, a portable computer, a web tablet, a wireless phone, a mobile phone, a digital music player, a memory card or a different system that can transmit and/or receive information.

According to the embodiments of the invention, the operation power of the phase change memory device can be reduced due to the phase change auxiliary pattern. Also, data retention characteristic and endurance characteristic of the phase change memory device can be improved. That is, the electrical characteristics and reliability of the phase change memory device can be enhanced.

The above-disclosed subject matter is to be considered illustrative, and not restrictive, and the appended claims are intended to cover all such modifications, enhancements, and other embodiments, which fall within the true spirit and scope of the invention. Thus, to the maximum extent allowed by law, the scope of the invention is to be determined by the broadest permissible interpretation of the following claims and their equivalents, and shall not be restricted or limited by the foregoing detailed description.

What is claimed is:

1. A phase change memory device comprising:
a first electrode and a second electrode;
a phase change material pattern interposed between the first and second electrodes; and
a phase change auxiliary pattern in contact with at least one side of the phase change material pattern,
the phase change auxiliary pattern comprising a compound having a chemical formula expressed as DₐM_{b}[GₓT_{y}]_{c}(0≦a/(a+b+c)≦0.2, 0≦b/(a+b+c)≦0.1, 0.3≦x/(x+y)≦0.7), where D comprises at least one of C, N, and O; M comprises at least one of a transition metal, Al, Ga, and In; G comprises Ge; and T comprises Te.

2. The phase change memory device of claim 1, wherein Gₓ is Geₓ₁G′ₓ₂ (0.8≦x1/(x1+x2)≦1), and G′ is an element selected from groups 3A, 4A or 5A.

3. The phase change memory device of claim 2, wherein G′ is Al, Ga, In, Si, Sn, As, Sb, or Bi.

4. The phase change memory device of claim 1, wherein T_{y} is Te_{y1}Se_{y2} (0.8≦y1/(y1+y2)≦1).

5. The phase change memory device of claim 1, further comprising an adhesive layer between the phase change auxiliary pattern and the first electrode or between the phase change auxiliary pattern and the second electrode, the adhesive layer comprising at least one of a transition metal, Al, Ga, and In.

6. The phase change memory device of claim 1, further comprising a barrier layer between the phase change material pattern and the phase change auxiliary pattern, the barrier layer comprising at least one of Ti, Ta, Mo, Hf, Zr, Cr, W, Nb, V, N, C, Al, B, P, O, and S.

7. The phase change memory device of claim 1, wherein the phase change material pattern comprises at least one of D1-Ge—Sb—Te, D2-Ge—Bi—Te, D3-Sb—Te, D4-Sb—Se, and D5-Sb, D1 comprising at least one of C, N, Si, Bi, In, As, and Se, D2 comprising at least one of C, N, Si, In, As, and Se, D3 comprising at least one of As, Sn, SnIn, an element from group 5B, and an element from group 6B, D4 comprising at least one of an element from group 5A, and an element from group 6A, and D5 comprising at least one of Ge, Ga and In.

8. A phase change memory device comprising:
a lower electrode on a substrate;
a phase change material pattern on the lower electrode;
a phase change auxiliary pattern on the phase change material pattern; and
an upper electrode on the phase change auxiliary pattern, the phase change auxiliary pattern comprising a compound having a chemical formula expressed as DₐM_{b}[GₓT_{y}]_{c}(0≦a/(a+b+c)≦0.2, 0≦b/(a+b+c)≦0.1, 0.3≦x/(x+y)≦0.7), where D comprises at least one of C, N, and O; M comprises at least one of a transition metal, Al, Ga, and In; G comprises Ge; and T comprises Te.

9. The phase change memory device of claim 8, wherein Gₓ is Geₓ₁G′ₓ₂ (0.8≦x1/(x1+x2)≦1), and G′ is Al, Ga, In, Si, Sn, As, Sb, or Bi.

10. The phase change memory device of claim 8, wherein T_{y} is Te_{y1}Se_{y2} (0.8≦y1/(y1+y2)≦1).

11. The phase change memory device of claim 8, further comprising an adhesive layer between the phase change auxiliary pattern and the upper electrode, the adhesive layer comprising at least one of a transition metal, Al, Ga, and In.

12. The phase change memory device of claim 8, further comprising a barrier layer between the phase change material pattern and the phase change auxiliary pattern, the barrier layer comprising at least one of Ti, Ta, Mo, Hf, Zr, Cr, W, Nb, V, N, C, Al, B, P, O, and S.
